(19) United States
(12) Patent Application Publication
(10) Pub. No.: US 2012/0298330 A1
(43) Pub. Date: Nov. 29, 2012

(54) AIR PATH RAIN GUARD FOR A COOLING SYSTEM OF A WEATHERPROOF ENCLOSURE FOR ELECTRICAL EQUIPMENT AND THE LIKE

(75) Inventor: Louis B. Mysse, III, Coeur dAlene, ID (US)

(73) Assignee: Purcell Systems, Inc., Spokane Valley, WA (US)

(21) Appl. No.: 13/301,568

(22) Filed: Nov. 21, 2011

Related U.S. Application Data
(60) Provisional application No. 61/415,678, filed on Nov. 19, 2010.

(51) Int. Cl. H05K 5/02; F28F 27/00

(52) U.S. Cl. 165/96; 454/184

(57) ABSTRACT

A weatherproof enclosure for electrical equipment or the like includes a cooling system with a water intrusion inhibiting device. The water intrusion inhibiting device includes a gutter positioned inside an outlet vent, and a flap between the gutter and a blower of the cooling system. The flap is movable between a closed position covering an opening between the gutter and the blower, and an open position allowing air to flow through the opening. When the blower is activated the pressure and air flow causes the flap to swing outwardly from the opening to an open position.

### RELATED APPLICATIONS

This application claims the benefit under 35 U.S.C. §119(e) of U.S. Provisional Patent Application No. 61/415,678, filed Nov. 19, 2010, which is incorporated herein by reference in its entirety.

### BACKGROUND

The field of the present disclosure relates to cooling systems for a cabinet or other enclosure, such as a weatherproof cabinet for containing electrical and electronic equipment of the kind used at telecommunication equipment sites. Electronic equipment enclosures are commonly located in outdoor environments, and often utilize a heat exchanger for cooling that isolates an internal chamber of the enclosure from the external environment, weather, rain, snow, etc. U.S. Pat. Nos. 6,889,752 of Stoller and 7,100,682 of Okamoto et al. describe cooling systems for such enclosures in which an internal airflow circuit is arranged adjacent an external airflow, but isolated therefrom via walls of a heat exchanger. Although such heat exchangers are designed to prevent water intrusion into the internal chamber, water may still enter the external cooling air flow through an air inlet vent or outlet vent in the enclosure housing so as to expose the fans of the external airflow to weather. Okamoto '682 provides an external airflow duct including a drain structure for capturing and draining water that may enter an outlet vent, to thereby prevent such water from collecting where the heat exchanger structure is sealed to walls of the internal chamber and leaking therethrough into the internal chamber.

Many countries require certification of electrical equipment enclosures for outdoor use. Such certifications often require that no water touches a fan of the unit, regardless of whether the fan is on or off. In some instances it may be acceptable to use wet-rated fans, that is, fans that are designed to operate when exposed to some amounts of water, such as rain or water spray. However, wet-rated fans are more expensive than non-wet-rated fans. Another solution for providing a heat exchanger with a fan for outdoor use is to include a long and/or convoluted airflow path between external vents and the fan to prevent rain intrusion, as disclosed in U.S. Pat. No. 7,312,993 of Bundza et al. for example. However, long airflow paths generally inhibit airflow and reduce cooling system performance. A convoluted airflow path may also require an airflow duct that is large enough in cross sectional area to minimize pressure drop, which results in a relatively large heat exchanger, use of relatively large fans, or both. The present inventor has therefore recognized a need to provide improved weatherproof cooling systems for electronics cabinets and other electrical equipment enclosures.

### SUMMARY

Methods and systems are disclosed for improved cooling systems and improved operation of cooling systems and heat exchangers in environments where such devices are exposed to water, for example, in the form or rain, snow, sleet, or hail. In preferred systems and methods, a splash guard is included in a cooling system housing and may provide similar or better thermal performance for a cooling system in a similar or smaller form factor compared to current cooling systems. Including a splash guard may also permit use of lower cost and more readily available non-wet rated fans.

Some embodiments may include one or more of the above advantages, and/or other advantages. For example, according to one embodiment, a heat exchanger includes a water intrusion inhibiting device, or splash guard, located in a heat exchanger housing proximate an air outlet vent. A portion of the water intrusion inhibiting device includes a flap moveably connected to a portion of the inside of the heat exchanger housing. Another portion of the water intrusion inhibiting device includes a gutter located in the heat exchanger housing proximate the flap.

Additional aspects and advantages will be apparent from the following detailed description of preferred embodiments, which proceeds with reference to the accompanying drawings.

### BRIEF DESCRIPTION OF THE DRAWINGS

FIG. 1 is a front isometric view of a weatherproof enclosure or cabinet for electrical equipment including a cooling system.

FIG. 2 is an enlarged partial sectional view of an upper housing portion of the enclosure of FIG. 1, illustrating a splash guard of the cooling system shown in a closed position.

FIG. 3 is the enlarged partial sectional view of FIG. 2 with the splash guard shown in an open position.

FIG. 4 is a sectional schematic side elevation view of the heat exchanger of FIG. 1.

FIG. 5 is an enlarged side sectional elevation of an upper portion of the cooling system of FIG. 1 with the splash guard illustrated in the closed position.

FIG. 6 is an enlarged side sectional elevation of the upper portion of the cooling system of FIG. 1 with the splash guard illustrated in the open position.

FIG. 7 is an enlarged side sectional elevation of the heat exchanger of FIG. 1 with the splash guard illustrated in an open position and providing some preferred, exemplary dimensions.

FIG. 8 illustrates a sectional schematic view of an exemplary direct vented air flow path.

FIG. 9 illustrates a sectional schematic view of an exemplary convoluted air flow path.

### DETAILED DESCRIPTION OF PREFERRED EMBODIMENTS

Throughout this description, reference to “one embodiment,” “an embodiment,” or “some embodiments” means that a particular described feature, structure, or characteristic is included in at least one embodiment. Thus appearances of the phrases “in one embodiment,” “in an embodiment,” or “in some embodiments” in various places throughout this description are not necessarily all referring to the same embodiment.

Furthermore, the described features, structures, characteristics, and methods may be combined in any suitable manner in one or more embodiments. In view of the disclosure herein, those skilled in the art will recognize that the various embodiments can be practiced without one or more of the specific details or with other methods, components, materials, or the like. In other instances, well-known structures, materials, or operations are not shown or not described in detail to avoid obscuring aspects of the embodiments. For convenience, the methods and systems may be described herein with reference to heat exchangers used with telecommunication shelters, however, it is understood that the apparatuses and methods described herein are applicable to any heat exchanger used in an outdoor environment or other suitable location where a heat exchanger may be exposed to water or other liquids.

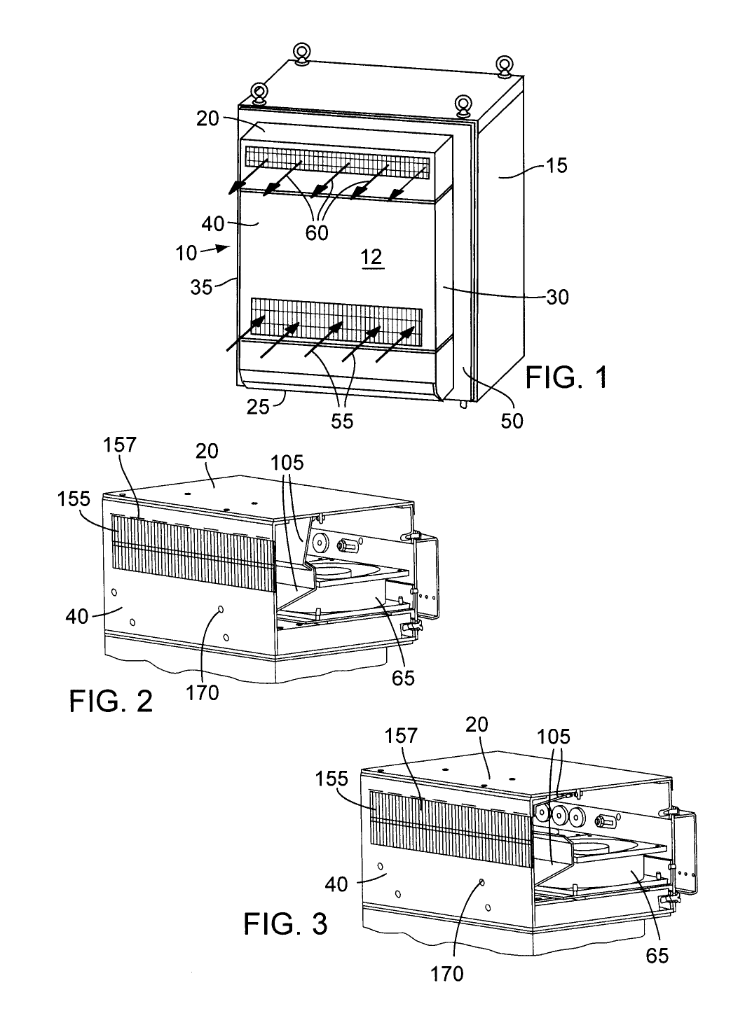

FIG. 1 illustrates a weatherproof enclosure 15 in the form of a cabinet with an internal compartment that houses electrical equipment (not shown), such as electronics for a telecommunication equipment site. With reference to FIG. 1, enclosure 15 includes a cooling system in the form of a heat exchanger 10 for cooling the internal compartment of enclosure 15. In the embodiment illustrated, heat exchanger 10 is mounted within a hollow door that provides access to the internal compartment of enclosure 15. In other embodiments, heat exchanger 10 may be mounted to a non-opening wall of enclosure 15. In still other embodiments, the cooling system may comprise a direct air cooling system that does not utilize a heat exchanger.

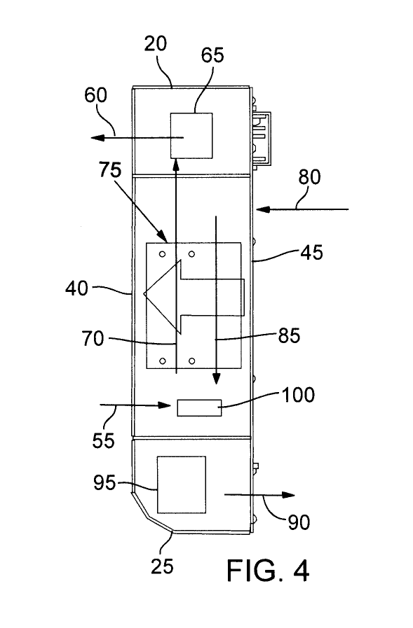

The door of enclosure 15 includes a housing 12 having a top wall 20, a bottom wall 25, a first side wall 30 extending between the top wall 20 and the bottom wall 25, a second side wall 35 extending between the top wall 20 and the bottom wall 25, a front wall (exterior wall 40) extending between the top wall 20, the bottom wall 25, and the first and second side walls 30 and 35, and a back wall 45 (as best viewed in FIG. 4) extending between the top wall 20, the bottom wall 25, and the first and second side walls 30 and 35. In other embodiments, a back wall, such as back wall 45, may not be provided and the front wall or door panel 50 of electronic enclosure 15 may serve as a back wall (inner panel) for the hollow door housing heat exchanger 10. In other embodiments (not shown), an access door of enclosure 15 may be separate from heat exchanger 10, which may be mounted directly to a non-opening panel of enclosure 15. The exterior wall 40 of housing 12 includes an inlet vent through which external cooling air 55 is drawn in and an outlet vent through which the flow of external cooling air is exhausted 60.

FIGS. 2 and 3 are partial sectional detail views of a top portion of heat exchanger 10 of FIG. 1 illustrating a splash guard 105 located in the housing 12 proximate top wall 20 thereof and between a fan 65 (or other blower or air moving device) and an outlet vent formed by slots 155 in exterior wall 40. Reference to fan 65 includes one fan or a plurality of fans. Fan 65 may include a wet rated fan or a non-wet rated fan. Including a non-wet rated fan may provide advantages of using lower cost components, more readily available components, or both. FIG. 2 illustrates splash guard 105 is a closed position when fan 65 is not operating. Splash guard 105 is moved to an open position illustrated in FIG. 3 when fan 65 is operating. The operation and function of the splash guard 105 in connection with operation of fan 65 is explained in further detail below.

FIG. 4 is a schematic side sectional elevation view of the heat exchanger of FIG. 1 illustrating ambient environmental air being moved by one or more blowers or air movers, such as fan 65, through a first airflow pathway 70 extending between an inlet vent in housing (designated by inlet flow 55), through a heat transfer core 75 (aka heat exchanger core) and over a heat exchange surface thereof, and to an outlet vent in exterior wall 40 of housing 12 (designated by exhaust flow 60). Internal enclosure air is moved through an internal airflow circuit extending from the internal compartment through a second fluid inlet 80 formed in back wall 45, a second path 85 though the heat transfer core 75, and a second fluid outlet 90 returning to the internal compartment. When the heat exchanger 10 is used to cool an enclosure, e.g. to remove heat generated by electronic devices within the enclosure, ambient environmental air is drawn through the airflow pathway 75 and internal enclosure air is circulated through the internal airflow circuit (80, 85, 90). The first and second airflow paths 70 and 85 pass through heat transfer core 75, preferably in a counter-flow arrangement. Heat exchanger 10 and heat transfer core 75 are preferably configured to permit heat to transfer from the internal enclosure air to the ambient external cooling air without mixing the internal enclosure air with the external cooling air. Separate air movers 95 are preferably contained within heat exchanger 10 to move internal enclosure air through the internal airflow circuit. In some embodiments, the heat exchanger 10 may also be used to heat internal enclosure air utilizing an optional heater 100 associated with the second airflow path 85.

The internal airspace of the electronics enclosure 15 is preferably completely sealed, or substantially sealed, from ambient environmental air, water, and contaminants surrounding the electronics enclosure 15. In one exemplary arrangement, the heat exchanger 10 includes three sections, an inner heat transfer core 75 (FIG. 4), an internal airflow circuit (80, 85, and 90) that supplies cooled air to the internal compartment of enclosure 15, and an external cooling air fan section 55, 70, 60 (FIG. 4) that draws ambient external air into the heat exchanger 10 and exhausts warmed air to the outdoor environment. The heat transfer core 75 includes an air-air heat transfer device as well as an ambient air inlet and a warm enclosure air inlet. The outer loop air flow enters the housing 12 proximate the bottom of the exterior wall 40, flows through the heat transfer core 75 toward top wall 20 and exhausts through an upper fan section. The inner loop air flow enters the housing 12 proximate the top of the back wall 45, flows through the heat transfer core 75 toward the bottom wall 25, and exits through a lower fan section back into the airspace in the electronics enclosure 15.

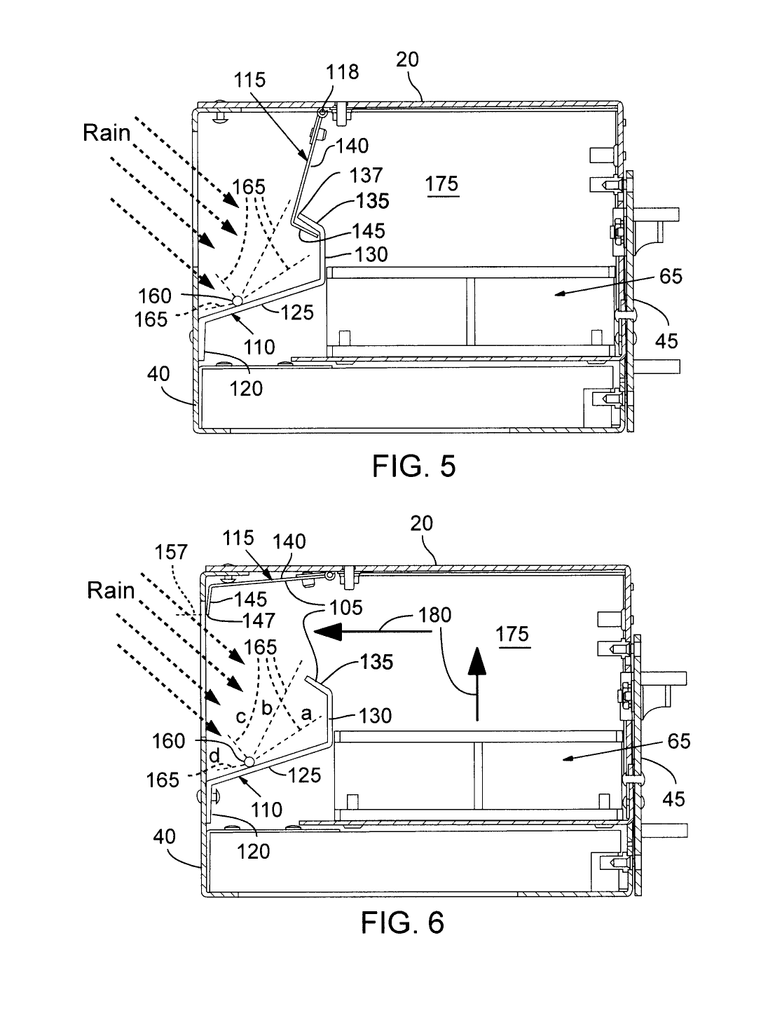

FIG. 5 illustrates a cross-sectional schematic view of splash guard 105 inhibiting water from reaching fan 65 when fan 65 is deactivated. FIG. 6 illustrates a cross-sectional schematic view of splash guard 105 inhibiting water from reaching fan 65 when fan 65 is activated. Operation and details of an exemplary splash guard 105 is now made with reference to FIGS. 5 and 6.

Splash guard 105 includes two main components, a gutter 110 and a flap 115. The gutter 110 is attached to an inside portion of the exterior wall 40 between fan 65 and the exterior wall 40. The gutter 110 may also be attached to side walls 30 and 35, or may alternately be attached to side walls 30 and 35 without being attached to exterior wall 40. The flap 115 is attached to an inside portion of the top wall 20 via a hinge 118, preferably at a location above at least a portion of gutter 110. The flap 115 may also be attached to side walls 30 and 35, or may be attached to side walls 30 and 35 without being attached to top wall 20, but is generally hung via a top portion of flap 115.

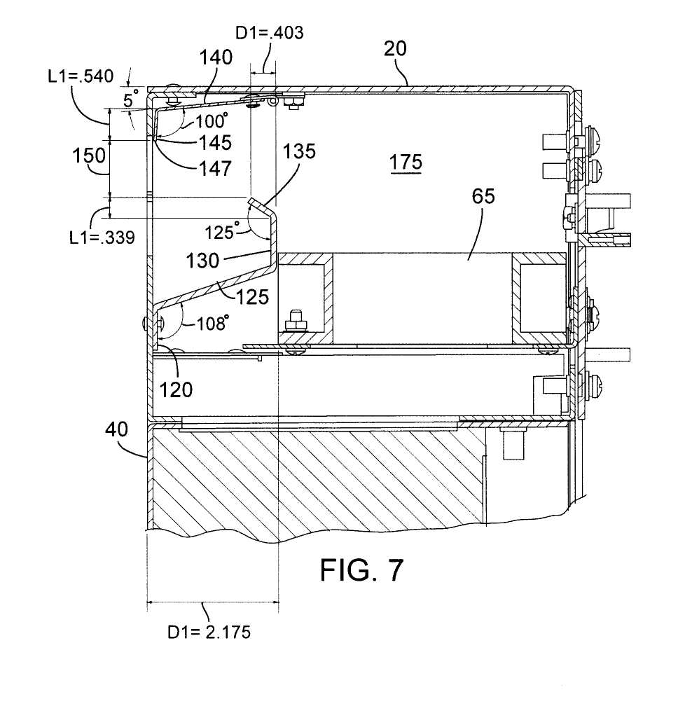

The gutter 100 is illustrated including an attachment portion 120, a first sloped portion forming a floor 125 that slopes downwardly toward exterior wall 40, a wall portion 130 (comprising, in the embodiment shown, a substantially vertical portion) spaced inwardly apart from exterior wall 40 and extending upwardly from floor 125, and a second sloped portion forming an overhanging portion 135 extending from the wall portion 130 and including a free edge 137 distal of the wall portion 130. The free edge 137 borders a bottom margin of an opening that is bordered along its top margin by top wall 20 and positioned between gutter and fan 65. The opening is covered by flap 115 when flap 115 is in the closed position as illustrated in FIG. 5. The flap 115 includes a major first surface 140 (main portion) and a second surface 145 in the form of a lip portion. When fan 65 is deactivated (FIG. 5), flap 115 automatically assumes the closed position, that is, flap 115 covers the opening between gutter 110 and top wall 20. In the closed position, the lip 145 of the flap 115 may rest against an underside of the overhanging portion 135 of gutter 110. When fan 65 is activated (FIG. 6), flap 115 is in an open position, that is, flap 115 uncovers the opening to provide an outlet headspace 150 (FIG. 7) defined between gutter 110 and flap 115. With reference to FIG. 7, some preferred embodiments include a ratio of L1:O of approximately 5:9, of O:L2 of approximately 9:3, and of L1:L2 of approximately 5:3.

Fluid outlet 60 preferably includes a structure that limits access to the interior of the heat exchanger housing 12 via the fluid outlet 60. Including an access limiting structure as part of fluid outlet 60 preferably prevents animals from entering or reaching through fluid outlet 60 and preferably prevents many insect species from entering through fluid outlet 60 to build nests or otherwise introduce debris into the heat exchanger housing 12. Such an access limiting structure may also inhibit water from entering though fluid outlet 60. Water, in the form of rain, snow, sleet, or hail may be wind driven toward fluid outlet 60. Some water may enter through fluid outlet 60, for example, by passing though the outlet vent defined in the embodiment shown by a plurality of slots 155, but some water is prevented from entering through fluid outlet 60, for example, by hitting a solid portion between slots 155. Still other water may hit a solid portion between slots 155 and become broken into a smaller form of water, such as water droplets (in the case of rain). Such water droplets may enter through one or more slots 155. An access limiting structure also inhibits the amount of wind that enters housing 12 through fluid outlet 60. As discussed below, inhibiting wind from entering, or controlling the amount of wind that enters, through fluid outlet 60 may advantageously help prevent water from reaching fan 65. In other embodiments, slots 155 are replaced by a different structure.

In one exemplary structure, an access limiting structure is formed by making two rows of rectangular-shaped slots 155 through the exterior wall 40. Each slot 155 is preferably approximately 0.125 of an inch wide and 1.0 inch high. Each slot 155 is separated by a distance of 0.062 of an inch. The first and second rows of slots 155 are separated by approximately 0.037 of an inch. Other suitable access limiting structures may be used. For example, the outlet vent may be covered by a grille, a mesh, a screen, or another structure that may limit access by animals and debris and inhibit raindrops from passing into housing 12. In one alternative embodiment, a screen having a mesh having 6 to 8 openings per linear inch (i.e., mesh size 6, 7, or 8) placed over the outlet vent defining fluid outlet 60.

When fan 65 is deactivated, water entering the heat exchanger housing 12 via fluid outlet 60 will encounter gutter 110, flap 115, or both. For example, a wind driven rain drop 160 entering through a slot 155 may impact the first sloped section 125 or the substantially vertical section 130 of gutter 110, or the first surface 140 or the second surface 145 of flap 115. Upon impact, rain drop 160 may break apart into droplets 165 which may scatter in various directions. However, a barrier formed by the engagement of flap 115 with gutter 110 prevents, or substantially prevents, water from reaching fan 65.

In the illustrated embodiment, the second surface 145 of flap 115 overlaps the overhanging portion 135 of gutter 110. Preferably, there is sufficient frictional force, or interference, between the second surface 145 (lip portion) of flap 115 and the overhanging portion 135 of gutter 110 to prevent wind from moving the flap 115 away from the overhanging portion 135. In one exemplary embodiment, the second surface 145 of flap 115 has a length between approximately 0.500 of an inch and approximately 0.600 of an inch, preferably approximately 0.542 of an inch, and an included angle between the first surface 140 and the second surface 145 of flap 115 is between approximately 110° and approximately 90°, preferably approximately 100°; the second sloped portion 135 of gutter 110 has a length between approximately 0.580 of an inch and approximately 0.600 of an inch, preferably approximately 0.591 of an inch, and an included angle between the substantially vertical portion 130 and the second sloped portion 135 is between approximately 115° and approximately 135°, preferably approximately 125°. The lengths of second surface 145 and of second sloped portion 135, as well as their respective included angles, may be modified depending on how much overlap and frictional force is desired when second surface 145 engages second sloped portion 135, the size or power of fan 65, or other suitable factor.

Water that enters through fluid outlet 60 and encounters the barrier formed by flap 115 engaging gutter 110 becomes trapped in gutter 110. For example, water drips from the first surface 140, the second surface 145, and the substantially vertical portion 130 to collect on the floor 125 and moves by the force of gravity toward exterior wall 40. To facilitate such trapped water leaving heat exchanger housing 12, one or more weeps or drains 170 (FIG. 2) may optionally be included through exterior wall 40. The drains 170 are preferably apertures with a diameter of approximately 0.125 of an inch and are located just above the junction where the floor 125 meets exterior wall 40. Other suitable drains may be included, and such drains may include screens or other suitable devices for permitting water to exit, but preventing insects or debris from entering the housing 12.

When fan 65 is activated, the pressure and airflow created by fan 65 urge flap 115 to an open position. In some embodiments, an optional motor, hydraulic actuator, or other suitable driving device (not shown) may be included to move flap 115 between a closed position and an open position. When fan 65 is deactivated, flap 115 is urged toward the closed position by gravity.

An exemplary open position for flap 115 is illustrated in FIGS. 3, 6, and 7 where flap 115 is proximate an inner portion of top wall 20. In other embodiments, flap 115 may not be proximate an inner portion of top wall 20, but may rotate or move, in whole or in part, toward top wall 20 a sufficient distance to provide a headspace 150 (FIG. 7) for the fluid outlet 60, having an adequate height. In one example, an adequate outlet headspace 150 may be expressed as the working cross sectional area of the fan 65 or fans (e.g. the working cross sectional area of a single fan times the number of fans) divided by the length of opening 150 (which correlates to the length of gutter 110 and of flap 115 in some arrangements). Alternately, an adequate outlet headspace 150 may be expressed as a height sufficient to produce relatively little noise, for example, by creating a relatively low amplitude, such as 65 dBa or lower, when air passes through the opening. In some embodiments, an adequate outlet headspace 150 may be expressed as a height sufficient to create a relatively low pressure drop, such as 0.64 inches of water or lower, when the external cooling air is exhausted. In one arrangement, an adequate outlet headspace 150 exhibiting a relatively low pressure drop and a relatively low amplitude is between approximately 0.900 of an inch and approximately 1.000 inch, preferably approximately 0.939 of an inch, when the opening is also approximately 20.55 inches long and 4 fans 65 of PFB1248UHE model made by Delta Electronics, Inc. of Taipei, Taiwan, R.O.C. are included in an arrangement adjacent the gutter. In some embodiments, an outlet headspace 150 may include one or more of the above properties, singularly or in any combination. In preferred arrangements, the outlet headspace 150 is no less than the cross sectional area of an outlet of one air mover, such as fan 65.

In the illustrated arrangement, flap 115 is made from 18 gage aluminum alloy, and is approximately 20.4 inches long. Fan 65 is a PFB1248UHE model made by Delta Electronics, Inc. and moves air at 450 inches per second. Other suitable air movers may be used and other suitable flap materials and thicknesses may be used in other arrangements.

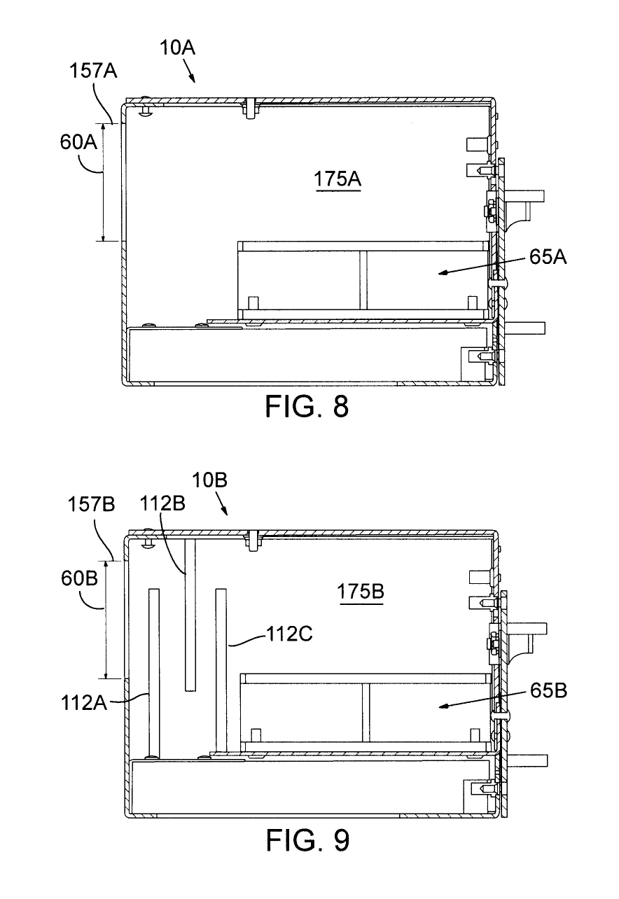

With flap 115 in the open position, the flap 115 and gutter 110 cooperate to form a partially convoluted air flow path. A partially convoluted air flow path is one that is between a direct-vented or “open” air flow path and a convoluted air flow path. For comparison, an exemplary open air flow path is illustrated in FIG. 8, showing a wet rated fan 65A. An open air flow path places no obstacles for air to flow around between an exit, such as fluid outlet 60A, and an airspace, such as the airspace 175A, above an air mover, such as wet rated fan 65A. An exemplary convoluted air flow path is illustrated in FIG. 9. A convoluted air flow path places obstacles, such as baffles 112A, 112B, and 112C, for air to flow around between an exit, such as fluid outlet 60B, and an airspace, such as the airspace 175B, above an air mover, such as fan 65B such that there is no direct path between the exit and the airspace. Because of the baffles 112A, 112B, and 112C and the pressure drop caused by such baffles, the heat exchanger 10B illustrated in FIG. 9 will have inferior thermal performance, i.e., less capacity to transfer heat out of an electronics enclosure, compared to the heat exchanger 10A illustrated in FIG. 8 assuming both heat exchangers are similarly sized. A partially convoluted air flow path is an air flow path that places one or more obstacles for air to flow around between an exit, such as fluid outlet 60, and an airspace, such as the airspace 175, above an air mover, such as fan 65 such that there is at least one direct path between the exit and the airspace. An exemplary partially convoluted air flow path is illustrated in FIG. 6. Preferably, the thermal performance of heat exchanger 10 (which uses a fan 65) is similar to the thermal performance of the heat exchanger 10A (which uses a wet rated fan 65A) assuming both heat exchangers are similarly sized.

With flap 115 in an open position, wind driven rain, or other water, may enter heat exchanger 10 through fluid outlet 60, for example, through slots 155. As discussed above, some water may enter in a relatively large form, such as raindrops 160, and some water may enter in a smaller form, such as water droplets 165. Obstacles in the partially convoluted air flow path 180 are preferably shaped, dimensioned, and positioned to inhibit water from reaching fan 65 and to maintain a relatively low pressure drop, such as approximately 0.64 inches of water or less.

The flap 115 may preferably create an airflow guiding structure for the partially convoluted air flow path 180, even though flap 115 does not project into the direct path between fluid outlet 60 and the airspace 175 above fan 65. In the illustrated arrangement, the second surface 145 presents a substantially vertical surface that guides air in an upper portion of the partially convoluted air flow path 180. An edge 147 of the second surface 145 preferably contacts an inner portion of exterior wall 40 at or near a location proximate to an upper boundary 157 formed by upper edges of slots 155. The first surface 140 and the second surface 145 of flap 115 help guide flowing air in the partially convoluted air flow path 180 downward toward slots 155 and out through fluid outlet 60. Thus, an upper layer of air flowing through partially convoluted air flow path 180 exits slots 155 in a downward direction which in turn urges water entering slots 155 toward gutter 110.

Alternately, the flap 115 may constitute an obstacle in the direct path between fluid outlet 60 and airspace 175. For example, a portion of the second surface 145 may extend below an upper boundary 157 of slots 155. In such embodiments, raindrops may be broken apart by impacting the second surface 145.

An obstacle in the partially convoluted air flow path 180 may also be created by gutter 110. In the illustrated arrangement, some of the substantially vertical portion 130 and all of the second sloped portion 135 project into the direct path between fluid outlet 60 and the airspace 175 above fan 65. In other arrangements, more or less of gutter 110 may project into such a direct path. In other arrangements, more obstacles may be included. Some air flowing through partially convoluted air flow path 180 must flow around the section of the substantially vertical portion 130 and the second sloped portion 135 projecting into the direct path between fluid outlet 60 and the airspace 175. Such air is deflected toward a central portion of the flowing airstream where faster flowing air directs such deflected air out through fluid outlet 60.

In a preferred embodiment, when flap 115 is in the fully open position, an imaginary straight line drawn between a distal edge of the lip portion 145 and the free edge 137 of overhanging portion 135 forms an angle of less than 45° relative to horizontal or more preferably less than 30° relative to horizontal, or about 28° relative to horizontal.

In some embodiments an access limiting structure, such as the two rows of slots 155, may be considered as another obstacle in a partially convoluted air flow path.

A relatively substantial portion of air flowing through partially convoluted air flow path 180 flows directly from the airspace 175 and out through fluid outlet 60.

Wind driven rain, or other suitable water, entering through slots 155 is directed toward gutter 110 by air flowing through partially convoluted air flow path 180, gravitational forces, the wind driving the rain, or by any two or all three. Because wind forces can be strong, inhibiting wind from entering, or controlling the amount of wind that enters, through fluid outlet 60 is important in some embodiments. Including an access limiting structure, such as the two rows of slots 155 preferably helps prevent water from reaching fan 65 by reducing the amount and force of wind that can enter housing 12. For example, when fan 65 is a PFB1248UHE model made by Delta Electronics, Inc. moving air at 450 inches per second, adding a third row of slots 155 may permit sufficient wind to enter housing 12 to cause water to reach the fan 65 when it is activated.

As discussed above, some water may enter in a relatively large form, such as raindrops 160, and some water may enter in a smaller form, such as droplets 165. Water entering housing 12 in a smaller form is preferably redirected by air flowing through partially convoluted air flow path 180 to exit housing 12 through fluid outlet 60, preferably before such water contacts gutter 110 or other internal component of heat exchanger 10. Or, the force of air flowing though partially convoluted air flow path 180 may be sufficiently strong to prevent water in a smaller form from entering through fluid outlet 60. However, raindrops 160 or other suitable water forms may have sufficient mass and velocity to have their trajectories affected by air flowing though partially convoluted air flow path 180, but not reversed by such flowing air. In other words, air flowing through partially convoluted air flow path 180 may not be sufficiently forceful to prevent relatively large water forms from entering through slots 155.

Relatively large water forms that enter through fluid outlet 60 without being broken apart by solid material between slots 155 impact gutter 110 and are broken apart into smaller water forms, such as droplets 165. Many droplets 165 are contained by gutter 110, for example, water droplets 165 following path “a”, “c”, or “d” illustrated in FIG. 6. In the illustrated arrangement, gutter 110 forms a C-shape, or cupped-shape, to inhibit water from reaching fan 65. Other suitable shapes may be used in other embodiments, such as an L-shape.

Some smaller water forms may not be contained by gutter 110 and may enter partially convoluted air flow path 180. For example, water droplets 165 following path “b”. In the illustrated arrangement, the force of air flowing through partially convoluted air flow path 180 is sufficiently strong to carry such water that is not contained by gutter 110 either back into gutter 110 or out through fluid outlet 60. In a manner similar to when fan 65 is deactivated, water contained or trapped by gutter 110 is removed from the interior of heat exchanger 10, for example, through drains 170.

The combination of flap 115, gutter 110, and air flowing through partially convoluted air flow path 180 thus cooperate to prevent, or substantially prevent, water from reaching fans 65.

The arrangement illustrated in FIGS. 1-7 preferably meets the requirements for Underwriters Laboratories (“UL”) certification for enclosures for electrical equipment for outdoor use with fans. For example, the illustrated arrangement preferably does not permit any water to touch the fans 65, as specified by UL 50E titled “Enclosures for Electrical Equipment, Environmental Considerations,” First Edition, Sep. 4, 2007.

It will be obvious to those having skill in the art that many changes may be made to the details of the above-described embodiments without departing from the underlying principles of the invention.

1. A weatherproof enclosure for electrical equipment, comprising:
a housing including an exterior wall;
an internal compartment for containing electrical equipment;
an airflow pathway formed in the housing, the airflow pathway extending between an inlet vent and an outlet vent formed in the exterior wall of the housing;
a blower retained in the housing proximate the outlet vent for drawing external cooling air into the airflow pathway through the inlet vent and over a heat exchange surface, and for exhausting the external cooling air through the outlet vent;
a gutter positioned inside the exterior wall of the housing beneath the outlet vent and along the airflow pathway between the blower and the outlet vent; and
a flap positioned within the housing between the gutter and the blower, the flap moveable between a closed position in which the flap covers an opening between the gutter and the blower and an open position in which at least a portion of the flap is away from the opening for allowing the external cooling air to flow through the opening and exhaust through the outlet vent.

2. The enclosure of claim 1, wherein the flap is movable to the open position by the flow of the external cooling air when the blower is operating, and the flap automatically returns to the closed position when the blower is not operating.

3. The enclosure of claim 1, wherein the gutter and the flap cooperate to form a partially convoluted flow path when the flap is in the open position.

4. The enclosure of claim 1, further comprising a drain formed through the exterior wall to allow liquid to drain from the gutter.

5. The enclosure of claim 1, wherein the gutter includes a floor sloping downwardly toward the exterior wall, a wall portion spaced inwardly from the exterior wall and extending upwardly from the floor, and an overhanging portion extending from the wall portion toward the exterior wall, the overhanging portion including a free edge distal of the wall portion and bordering the opening.

6. The enclosure of claim 5, wherein the flap includes a lip that extends under the overhanging portion of the gutter when the flap is in the closed position.

7. The enclosure of claim 6, wherein the flap hangs from a hinge supported on the housing, and the flap is urged toward the closed position by gravity.

8. The enclosure of claim 6, wherein the lip rests against an underside of the overhanging portion of the gutter when the flap is in the closed position.

9. The enclosure of claim 6, wherein:
the flap includes a main portion rotatably connected to the housing via a hinge and depending downwardly from the hinge; and
the lip is connected to a distal end of the main portion and extends transversely away from the main portion so as to form an obtuse included angle therebetween.

10. The enclosure of claim 1, wherein the outlet vent is defined by a collection of slots in the exterior wall of the housing.

11. The enclosure of claim 1, wherein the blower includes a plurality of fans arranged adjacent the opening.

12. The enclosure of claim 1, wherein the airflow pathway is contained within a hollow door that provides access to the internal compartment of the enclosure.

13. The enclosure of claim 11, further comprising a heat exchanger core mounted within the door and positioned in the airflow pathway.

14. The enclosure of claim 13, further comprising an internal airflow circuit extending from the internal compartment, through an internal wall of the door, and through the heat exchanger core, the internal airflow circuit arranged so that air flowing along the internal airflow circuit does not mix with the external cooling air flowing through the airflow pathway.

15. The enclosure of claim 14, wherein the airflow pathway, the internal airflow circuit, and the heat exchanger core are arranged in a counter-flow configuration.

16. The enclosure of claim 3, wherein:
the flap includes a major first surface connected to a second surface to form an included angle there between;
the first surface is substantially horizontal and the second surface is substantially vertical when the flap is in the second position; and
the first surface is substantially vertical and the second surface is substantially horizontal and engages a portion of the gutter when the flap is in the first position.

17. The enclosure of claim 5, wherein:
the flap includes a first surface connected to a second surface to form an included angle there between;
the first surface is substantially horizontal and the second surface is substantially vertical when the flap is in the open position;
the first surface is substantially vertical and the second surface is substantially horizontal and engages the overhanging portion of the gutter to facilitate holding the flap in position when the flap is in the closed position; and
the flap and the gutter cooperating when the flap is in the open position to form a partially convoluted flow path having a height defined by a vertical distance between the free edge of the overhanging portion of the gutter and a distal end of the second surface of the flap.

18. The enclosure of claim 17, wherein the height of the partially convoluted flow path is equal to or greater than a working cross sectional area of the blower divided by a length of the opening.

19. An enclosure for electrical equipment, comprising:
a housing means containing an internal compartment and a heat exchange surface;
a blower means for moving ambient environmental air over the heat exchange surface; and
a splash guard means located in the housing means for substantially preventing water from reaching the blower means regardless of whether the blower means is operating.

20. A heat exchanger of claim 19, wherein the splash guard means includes:
a gutter means for breaking up water droplets and for capturing water;
a drain means for removing water captured by the gutter means; and
a flap means for covering an opening when the blower means is off and for substantially uncovering the opening when the blower means is on.
